(19) United States
(12) Patent Application Publication
(10) Pub. No.: US 2006/0194064 A1
(43) Pub. Date: Aug. 31, 2006

(54) Underfill encapsulant for wafer packaging and method for its application

(76) Inventors: Allison Yue Xiao, Belle Mead, NJ (US); Gyanendra Dutt, Piscataway, NJ (US)

Correspondence Address: NATIONAL STARCH AND CHEMICAL COMPANY, P.O. BOX 6500, BRIDGEWATER, NJ, 08807-3300, US

(21) Appl. No.: 11/351,647

(22) Filed: Feb. 10, 2006

Related U.S. Application Data
(63) Continuation-in-part of application No. 10/084,869, filed on Mar. 1, 2002, now Pat. No. 7,037,399.

(51) Int. Cl. B32B 27/38; H01L 21/56; C08L 63/00; B32B 37/00

(52) U.S. Cl. 428/414; 438/127; 523/400

(57) ABSTRACT

A curable underfill encapsulant composition that is applied directly onto semiconductor wafers before the wafers are diced into individual chips. The composition comprises a thermally curable epoxy resin, a solvent, an imidazole phosphate salt catalyst, fluxing agents, and optionally, wetting agents. Various other additives, such as defoaming agents, adhesion promoters, flow additives and rheology modifiers may also be added as desired. The underfill encapsulant is B-stageable to provide a coating on the wafer that is smooth, non-tacky and will allow the wafer to be cleanly diced into individual chips. A method for producing an electronic package containing the B-stageable material may also utilize an unfilled liquid curable fluxing material on the substrate to which the chip is to be attached.

### RELATED APPLICATIONS

The present application is a continuation-in-part application of U.S. pending patent application Ser. No. 10/084,869, filed Mar. 1, 2002.

### FIELD OF THE INVENTION

The present invention is related to an underfill encapsulant and a method for its application to semiconductor wafers.

### BACKGROUND OF THE INVENTION

This invention relates to underfill encapsulant compounds prepared from epoxies to protect and reinforce the interconnections between an electronic component and a substrate in a microelectronic device. Microelectronic devices contain multiple types of electrical circuit components, mainly transistors assembled together in integrated circuit (IC) chips, but also resistors, capacitors, and other components. These electronic components are interconnected to form the circuits, and eventually are connected to and supported on a carrier or a substrate, such as a printed wire board. The integrated circuit component may comprise a single bare chip, a single encapsulated chip, or an encapsulated package of multiple chips. The single bare chip can be attached to a lead frame, which in turn is encapsulated and attached to the printed wire board, or it can be directly attached to the printed wire board. These chips are originally formed as a semiconductor wafer containing multiple chips. The semiconductor wafer is diced as desired into individual chips or chip packages.

Whether the component is a bare chip connected to a lead frame, or a package connected to a printed wire board or other substrate, the connections are made between electrical terminations on the electronic component and corresponding electrical terminations on the substrate. One method for making these connections uses polymeric or metallic material that is applied in bumps to the component or substrate terminals. The terminals are aligned and contacted together and the resulting assembly is heated to reflow the metallic or polymeric material and solidify the connection.

During its normal service life, the electronic assembly is subjected to cycles of widely varying temperature ranges. Due to the differences in the coefficient of thermal expansion for the electronic component, the interconnect material, and the substrate, this thermal cycling can stress the components of the assembly and cause it to fail. To prevent the failure, the gap between the component and the substrate is filled with a polymeric encapsulant, hereinafter called underfill or underfill encapsulant, to reinforce the interconnect material and to absorb some of the stress of the thermal cycling.

Two prominent uses for underfill technology are for reinforcing packages known in the industry as chip scale packages (CSP), in which a chip package is attached to a substrate, and flip-chip packages in which a chip is attached by an array of interconnections to a substrate.

In conventional capillary flow underfill applications, the underfill dispensing and curing takes place after the reflow of the metallic or polymeric interconnect. In this procedure, flux is initially applied on the metal pads on the substrate. Next, the chip is placed on the fluxed area of the substrate, on top of the soldering site. The assembly is then heated to allow for reflow of the solder joint. At this point, a measured amount of underfill encapsulant material is dispensed along one or more peripheral sides of the electronic assembly and capillary action within the component-to-substrate gap draws the material inward. After the gap is filled, additional underfill encapsulant may be dispensed along the complete assembly periphery to help reduce stress concentrations and prolong the fatigue life of the assembled structure. The underfill encapsulant is subsequently cured to reach its optimized final properties.

Recently, attempts have been made to streamline the process and increase efficiency by coating the underfill encapsulant directly on the semiconductor wafer before the wafer is diced into individual chips. The coating procedure, which can be performed via various methods, including screen printing, stencil printing and spin coating, allows for a single application of underfill to a single semiconductor wafer that is later diced into a large number of individual chips.

In order to be useful as a wafer level underfill encapsulant, the underfill must have several important properties. First, the material must be easy to apply uniformly on the wafer so that the entire wafer has a consistent coating. The underfill encapsulant that is applied to the wafer must not interfere with the clean dicing of the wafer into individual chips. The underfill encapsulant must be B-stageable, which means that the underfill must be solidified after its placement on a wafer to provide a smooth, non-tacky coating with minimal residual solvent.

If the starting underfill material is a solid, the solid is dispersed or dissolved in a solvent to form a paste and the paste applied to the wafer. The underfill is then heated to evaporate the solvent, leaving a solid, but uncured, underfill on the wafer. If the starting underfill material is a liquid or paste, the underfill is dispensed onto the wafer and heated to partially cure it to a solid state.

The B-stage process usually occurs at a temperature lower than about 150° C. without prematurely curing the underfill encapsulant. The final curing of the underfill encapsulant must be delayed until after the solder fluxing (in the situation that solder is the interconnect material) and interconnection, which occurs at a temperature of 183° C. in the case of tin/lead eutectic solder and greater than 200° C. in the case of lead free solder. The final curing of the underfill should occur rapidly after the solder bump flow and interconnection. During this final attachment of the individual chips to a substrate, the underfill encapsulant must flow in order to enable fillet formation, flux the solder bumps, and provide good adhesion between the chip, or chip passivation layer, the substrate, or the solder mask, and the solder joints. In particular instances, it can be useful to provide an unfilled liquid curable fluxing material directly on the substrate to faciliate interconnection.

### BRIEF DESCRIPTION OF THE FIGURE

FIG. 1 is DSC curing thermograms.

### SUMMARY OF THE INVENTION

The invention relates to a curable underfill encapsulant composition that is applied directly onto semiconductor wafers before the wafers are diced into individual chips. The composition comprises a thermally curable resin system comprising an epoxy resin, a solvent, an imidazole-anhydride catalyst, and optionally, fluxing agents. Various other additives, such as defoaming agents, wetting agents, adhesion promoters, flow additives and rheology modifiers may also be added as desired. In an alternative embodiment, the imidazole-anhydride catalyst is replaced with an imidazole phosphate salt. The underfill encapsulant is B-stageable to provide a coating on the wafer that is smooth, non-tacky and will allow the wafer to be cleanly diced into individual chips. The individual chips are then attached directly to a substrate.

### DETAILED DESCRIPTION OF THE INVENTION

The resins used in the underfill encapsulant composition of the present invention are curable compounds, which means that they are capable of polymerization. As used in this specification, to cure will mean to polymerize, with cross-linking. Cross-linking, as understood in the art, is the attachment of two-polymer chains by bridges of an element, a molecular group, or a compound, and in general takes place upon heating.

Ingredients of the B-stageable underfill encapsulant composition of the present invention include a blend of one or more epoxy resins, an imidazole-anhydride adduct which acts as a catalyst and one or more solvents. In the alternative embodiment, the imidazole-anhydride adduct is replaced with an imidazole phosphate salt that acts as a catalyst. Optionally, fluxing agents, air release agents, flow additives, adhesion promoters, rheology modifiers, surfactants and other ingredients may be included. The ingredients are specifically chosen to obtain the desired balance of properties for the use of the particular resins. A solvent is chosen to dissolve the resin(s) and thus make the composition into a paste form with proper viscosity for application via spin coating, screen printing or stencil printing on the wafer. In the preferred embodiment, the composition is B-stageable, i.e., the composition is capable of an initial solidification that produces a, smooth, non-tacky coating on the semiconductor wafer. The B-stage solidification preferably occurs in at a temperature in the range of about 80° C. to about 160° C. After the B-stage process, a smooth, non-tacky solid coating is obtained on the wafer to ensure the clean dicing of the wafer into individual chips. The final, complete curing occurs at a second temperature of about 180° C. or above, which is higher than the B-stage curing temperature. Generally, the final cure of the composition occurs after the formation of the interconnections. In the case of Pb/Sn eutectic solder, the formation of the interconnections occurs at a temperature above the melting point of the solder, which is 183° C. In the case of lead free solder, the formation of the interconnections occurs at a temperature of about 217° C. for AgSnCu and about 225° C. for AgCu solder alloy. A latent catalyst, the adduct of anhydride and imidazole or imidazole phosphate salt, is used in the composition to ensure the proper cure of the composition without interfering with the formation of the interconnection. The catalyst chosen must prevent any curing, other than some minimal pre-curing, during the B-stage and must ensure that no gelation occurs on the non-tacky surface formed after the B-stage. Preferably, the B-stage solidification occurs at a temperature of at least 30° C. less than the final cure temperature. The catalyst must also allow for fluxing and curing in one reflow step. The underfill must first flux and then cure to ensure proper solder interconnect formation.

Examples of epoxy resins suitable for use in the present wafer level underfill composition include monofunctional and multifunctional glycidyl ethers of Bisphenol-A and Bisphenol-F, aliphatic and aromatic epoxies, saturated and unsaturated epoxies, or cycloaliphatic epoxy resins or a combination thereof. Examples of aliphatic epoxy include Flex Epoxy 1.

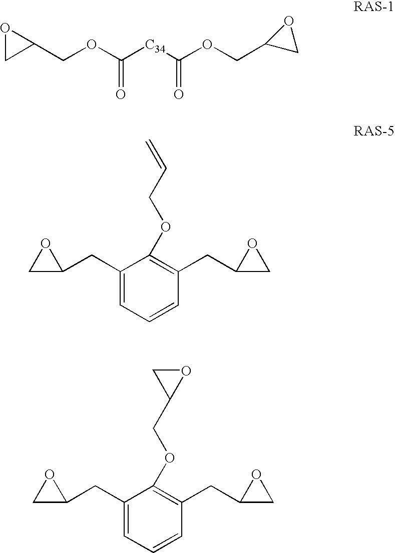

Example of aromatic epoxies include RAS-1, RAS-5 and Flex Epoxy3. 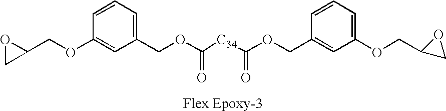
Example of unsaturated epoxy includes Cardolite NC513.

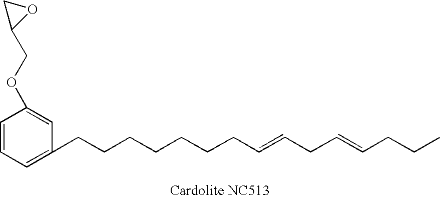

Examples of non-glycidyl ether epoxides include 3,4-epoxycyclohexylmethyl-3,4-epoxycyclohexane carboxylate, which contains two epoxide groups that are part of the ring structures and an ester linkage, vinylcyclohexene dioxide, which contains two epoxide groups and one of which is part of the ring structure, 3,4-epoxy-6-methyl cyclohexyl methyl-3,4-epoxycyclohexane carboxylate and dicyclopentadiene dioxide.

Glycidyl ether epoxides are preferred in the invention, either separately or in combination with the non-glycidyl ether epoxides. A preferred epoxy resin of this type is bisphenol A resin. Another preferred epoxy resin is bisphenol F type resin. A preferred epoxy novolac resin is poly(phenyl glycidyl ether)-co-formaldehyde. Biphenyl type epoxy resin may also be utilized in the present invention. This type of resin is commonly prepared by the reaction of biphenyl resin and epichlorohydrin. Dicyclopentadiene-phenol epoxy resin, naphthalene resins, epoxy functional butadiene acrylonitrile copolymers, epoxy functional polydimethyl siloxane and mixtures thereof are additional types of epoxy resins which may be employed. Commercially available bisphenol-F type resins are available from CVC Specialty Chemicals, Maple Shade, N.J. , under the designation 8230E and Resolution Performance Products LLC under the designation RSL1739. Bisphenol-A type resin is commercially available from Resolution Technology as EPON 828, EPON 1001, EPON 1002, and a blend of bisphenol-A and bisphenol-F is available from Nippon Chemical Company under the designation ZX-1059. A further epoxy that may be utilized is XP71756.00, which is commercially available from Vantico.

In addition to the resins, an imidazole-anhydride adduct or imidazole phosphate salt is included in the underfill composition as a catalyst. The adduct provides different properties to the underfill than the properties provided by the inclusion of imidazole and anhydride as separate components. The salt provides different properties to the underfill than the properties provided by the inclusion of imidazole and phosphoric acid as separate components. Preferred imidazoles that may be included in the adduct or salt include non-N-substituted imidazoles such as 2-phenyl-4-methyl imidazole, 2-ethyl-4-methyl-imidazole, 2-phenyl imidazole, 2-methyl imidazole and imidazole. Other useful imidazole components include alkyl-substituted imidazole, N-substituted imidazole, N-methylimidazole and mixtures thereof. The salt also comprises a phosphoric acid component. Preferred catalysts include 2-phenyl-imidazole dihydrogen phosphate salt, commercially available from Air Products as AMICURE 2PIP and 2-heptadecylimidazole, commercially available from Curezol and CUREZOL 17 A. The adduct also comprises an anhydride component. The preferred anhydride is preferably a cycloaliphatic anhydride and most preferably pyromellitic dianhydride, commercially available as PMDA from Aldrich. Additional preferred anhydrides include methylhexa-hydro phthalic anhydride, commercially available as MHHPA from Lonza Inc. Intermediates and Actives. Other anhydrides that may be utilized include methyltetra-hydrophthalic anhydride, nadic methyl anhydride, hexa-hydro phthalic anhydride, tetra-hydro phthalic anhydride, phthalic anhydride, dodecyl succinic anhydride, bisphenyl dianhydride, benzophenone tetracarboxylic dianhydride, and mixtures thereof. A preferred catalyst is synthesized by combining 1 mole part 1,2,4,5-benzenetetracarboxylic dianhydride and 2 mole part 2-phenyl-4-methyimidazole. Both components are first dissolved in acetone under heat and when both are combined, the imidazole-dianhydride salt forms as a precipitate. This preferred catalyst, in combination with an epoxy and solvent, produces an underfill having an onset curing temperature well above 160° C. and a cure peak temperature above 183° C. Further, the preferred catalyst provides improved latency as opposed to the use of just an imidazole.

A fluxing agent may also be incorporated into the underfill composition. The fluxing agent primarily removes metal oxides and prevents reoxidation. While many different fluxing materials may be employed, the fluxing agent is preferably chosen from the group carboxylic acids. These carboxylic acids include rosin gum, dodecanedioic acid (commercially available as Corfree M2 from Aldrich), adipic acid, sebasic acid, polysebasic polyanhydride, maleic acid, tarrtaric acid, and citric acid. The flux agent may also be chosen from the group that includes alcohols, hydroxyl acid and hydroxyl base. Preferable fluxing materials include polyols such as ethylene glycol, glycerol, 3-[bis(glycidyl oxy methyl)methoxy]-1,2-propane diol, D-ribose, D-cellobiose, cellulose, 3-cyclohexene-1,1-dimethanol and similar materials. The strength of the acid is an important factor because the acid should be sufficiently strong to wash the oxides out of the solder and the substrate. Preferably, the pKₐ should be greater than 5. Stability of the acid at temperatures around 183° C. is important, and the acid should not decompose at temperatures lower than 183° C. As solder reflows at 183 ° C., a flux material that cannot withstand that temperature is unsuitable for the proper formulation.

A solvent is utilized to modify the viscosity of the composition. Preferably, the solvent will evaporate during the B-stage process which occurs at temperatures lower than about 150° C. Common solvents that readily dissolve the epoxy resins, are non-reactive and have the proper boiling point ranging from 100° C. to 200° C. are preferable for use with this application. Examples of solvents that may be utilized include ketones, esters, alcohols, ethers, and other common solvents that are stable and dissolve the epoxy and phenolic resins in the composition. Preferred solvents include γ-butyrolactone and propylene glycol methyl ethyl acetate (PGMEA).

Additional ingredients may be added to the underfill encapsulant to produce a composition with the desired properties. For example, monofunctional reactive diluents can incrementally delay the increase in viscosity without adversely affecting the physical properties of the cured underfill. Preferred diluents include p-tert-butyl-phenyl glycidyl ether, allyl glycidyl ether, glycerol diblycidyl ether, glycidyl ether of alkyl phenol (commercially available from Cardolite Corporation as Cardolite NC513), and Butanediodiglycidylether (commercially available as BDGE from Aldrich), although other diluents may be utilized. Surfactants may be utilized to aid in the prevention of process voiding during the flip-chip bonding process and subsequent solder joint reflow and material curing. Various surfactants which may be utilized include organic acrylic polymers, silicones, polyoxyethylene/polyoxypropylene block copolymers, ethylene diamine based polyoxyethylene/polyoxypropylene block copolymers, polyol-based polyoxyalkylenes, fatty alcohol-based polyoxyalkylenes, fatty alcohol polyoxyalkylene alkyl ethers and mixtures thereof. In addition, coupling agents, air release agents, flow additives, adhesion promoters, inorganic fillers and other ingredients may also be added as desired.

A preferred embodiment of the u nderfill encapsulant of the present invention comprises at least one epoxy resin, an imidazole-anhydride adduct as a catalyst, a fluxing agent, solvent, and other ingredients as desired. The resin will comprise in the range of 20 wt % to about 90 wt % of the underfill composition. An imidazole-anhydride adduct is also added as a catalyst. The adduct comprises in the range of about 0.01 wt % to about 10 wt % of the underfill composition and preferably about 0.1 wt % to about 5 wt % of the composition. Optionally, a fluxing agent is added comprising in the range of about 0.5 wt % to about 20 wt % of the composition and preferably in the range of about 1 wt % to about 10 wt % of the composition. In addition, up to 80 wt % of solvent(s) may be added. Finally, optional ingredients such as surfactants, air release agents, flow additives, rheology modifiers, inorganic fillers and adhesion promoters may be added to the composition in the range of about 0.01 wt % to about 5 wt % of the composition.

A further preferred embodiment of the underfill encapsulant of the present invention comprises at least one epoxy resin, an imidazole phosphate salt as a catalyst, a fluxing agent, solvent, inorganic filler and other ingredients as desired. The epoxy resin will comprise in the range of about 20 wt % to about 80 wt % of the underfill composition. An imidazole phosphate salt is added as a catalyst. The imidazole phosphate salt comprises in the range of about 0.01 wt % to about 10 wt % of the underfill composition and preferably about 0.1 wt % to about 5 wt % of the composition. Optionally, a fluxing agent is added comprising in the range of about 0.5 wt % to about 20 wt % of the composition and preferably in the range of about 1 wt % to about 10 wt % of the composition. In addition, the composition contains up to about 70 wt % of filler content and up to about 60 wt % of solvent(s). Finally, optional ingredients such as surfactants, air release agents, flow additives, rheology modifiers, and adhesion promoters may be added to the composition in the range of about 0.01 wt % to about 5 wt % of the composition.

To utilize the B-stageable underfill composition, it is first applied directly onto a semiconductor wafer or individual chip via screen printing, spin coating or stencil printing. The wafer or chip having the coating is heated to an initial, B-stage temperature in the range of about 100° C. to about 140° C. for about 10 minutes to one hour so that the composition is B-stage solidified in the form of a smooth, non-tacky and void-free film. In the case of a wafer, the wafer is diced into individual chips. The chips having the B-staged composition are placed on a substrate with the B-staged composition adjacent to the substrate and the entire assembly is heated to a temperature of approximately 183° C. (in the case that lead/tin solder is utilized). This second heating causes the formation of interconnections between the substrate and the chip and the fluxing of the solder balls on the chip.

In an alternative embodiment, a composition comprising an unfilled liquid curable fluxing material comprising an epoxy resin, a phenolic-containing compound and an imidazole/anhydride adduct or an imidazole phosphate salt is applied directly to the substrate prior to placement of the chip. After the underfill is B-stage solidified on the wafer and the wafer is diced into individual chips, the chip is placed on the substrate with the B-staged material adjacent to and in contact with the unfilled liquid curable material. The unfilled liquid curable material facilitates improved solder fluxing and interconnections between the substrate and the individual chips. When the composition of the alternative embodiment is placed on a substrate and a chip having the B-stageable composition is placed on the substrate, a superior interconnect is formed after the completion of the reflow process.

The invention may be better understood by reference to the following examples:

### EXAMPLE 1

Five underfill encapsulant compositions were formulated as set out in Table 1. To make each formulation, the epoxy was first dissolved into the solvent under heat. When clean rosin was used as the fluxing agent, as in formulation 1, it was added during this first step and heated until a homogenous epoxy-solvent-rosin mixture formed. The rosin that is added must first be treated to form a clean-rosin gum. The treatment consists of heating the commercial rosin in a vacuum oven to drive off any impurities to form a “clean” fluxing reagent. On the other hand, if Corfree M2 is used as the fluxing reagent, as in formulations 2-5, it is added only after the epoxy-solvent mixture has cooled to room temperature. The rest of the components (catalyst, wetting agent, and defoamer) are also added after the epoxy-solvent or epoxy-solvent-rosin material has cooled to room temperature. The material is then mixed thoroughly and vacuumed under room temperature to degas the underfill.

TABLE 1
Underfill Formulations

| | Epoxy | | Fluxing | | Wetting | |
|---|---|---|---|---|---|---|
| No. | Resin¹ | Solvent² | Agent³ | Catalyst⁴ | Agent⁵ | Defoamer⁶ |
| 1 | 57.00 | 40.00 | 2.85 | 0.29 | 0.29 | 0.29 |
| 2 | 55.04 | 38.63 | 5.50 | 0.28 | 0.27 | 0.28 |
| 3 | 57.00 | 40.00 | 5.7 | 0.29 | 0.29 | 0.29 |
| 4 | 70.70 | 29.60 | 7.07 | 0.35 | 0.71 | 0.71 |
| 5 | 70.70 | 29.60 | 7.07 | 0.35 | 0.71 | 0.71 |

¹EPON 1001 from Resolution Products for samples 1-3, and XP 71756,
also known as Tactix556, from Vantico for samples 4-5
²Solvent BLO (γ-butyrolactone) for samples 1-4 and PGMEA (propylene
glycol methyl ether acetate) for sample 5, both from Aldrich Chemical
³Fluxing Agent clean rosin for sample 1 (vacuumed under heat to rid of
impurities); Corfree M2 for sample 2-5
⁴Catalyst is imidazole-anhydride adduct
⁵Wetting Agent is G6715, 3-glycidoxypropylpentamethyl disiloxane from
United Technologies
⁶Defoamer BYK A500 (Chemie) for sample 1, phthalo blue (Plasticolors) for
sample 2, and Agitan 731(Ultra Additives) for samples 3-5.

The viscosities of the five formulations are listed in Table 2. The viscosities were measured using an Advanced Rheology Expansion System, made by Rheometric Scientific, with 25-mm parallel plates, at 1% strain, a steady pre-shear rate of 1 s⁻¹, and from the range of 1-100 rad/s at room temperature.

TABLE 2
Viscosities of Underfill Formulations

| Formulation | Viscosity (cP) |
|---|---|
| 1 | 5,550 |
| 2 | 3,350 |
| 3 | 4,600 |
| 4 | 4,360 |
| 5 | 12,070 |

The viscosities of the samples are all within the ranges necessary to screen and stencil print.

### EXAMPLE 2

In order to find the proper B-staging conditions, two criteria are desired. These criteria are that, after the B-stage, the material must be non-tacky and not cured. To test whether these criteria were met, eight glass slides were bumped with 20-mil solder balls. About 20 mil of formulation 1 listed in Table 1 was then stenciled onto the glass slides. Each slide was then placed into a 130° C. oven. Each slide was then B-staged for different times in the oven (30, 40, 50, 60, 70, 80, 90, or 100 minutes). After each slide had cooled, a wooden stick was placed atop the film to evaluate tackiness. If the wooden stick left a mark on the film, it was deemed tacky. If the wooden stick left no mark, it was considered non-tacky. To perform the cure test, each slide was placed through the eutectic solder reflow oven. After the slides had gone through the reflow profile, each slide was examined to determine if the solder had melted. When the solder melted, the curing time was considered as non-curable B-staging time: time left in the oven did not start the overall curing process. However, when the solder did not melt, the B-staging time was considered too long and already cured the underfill. The results are shown in Table 3.

TABLE 3
B-staged Properties of Underfill

| Time | | |
|---|---|---|
| (Minutes at 130° C.) | Tacky | Cured |
| 30 | Y | N |
| 40 | Y | N |
| 50 | N | N |
| 60 | N | N |
| 70 | N | Y |
| 80 | N | Y |
| 90 | N | Y |
| 100 | N | Y |

As shown in Table 3, when the underfill is B-staged for less than an optimal time the resulting film remained tacky to the touch. When the underfill is B-staged for longer than an optimal time, curing of the film is initiated and that has a detrimental affect on the attachment process. At 130° C. the optimal curing time is about 50-60 minutes. As the underfill's curing onset temperature is about 150° C., temperatures above 130° C. are rarely utilized for B-staging. Temperatures below 130° C. may be utilized, but the time required to reach the proper B-stage state are longer the lower the temperature.

### EXAMPLE 3

The proper Tg for B-staged underfill is critical. Diamond saws, as used for dicing wafers, can cleanly cut through materials having a Tg within the range of about 50-95° C. If the Tg is much higher than the target range, cracks can occur and break the B-staged underfill off the wafer. If the Tg is below 50° C., the film may become sticky during the dicing and stick to the diamond saw. Several formulations were made with low Tg and the observations are shown in Table 4. The temperature was ramped up at a rate of 5° C./min and the Tgs of each sample were measured by a TA Instruments thermomechanical analyzer using the TA analysis program. Formulation A and B are made similarly to the formulations in Table 1. Low Tg resins were used in these formulations (Formulation A consists of a mixture of EPON1001 and maleimides. Formulation B consists of EPON1001 and glycidal methacrylate). Table 4 also illustrates the Tg of the five samples of Table 1. The Tgs of these five samples fall within the diceable range (50-90° C.) and have shown to be diceable.

TABLE 4
Dicing Properties of Underfills

| Formulation | Tg (° C.) | Dicing Observations |
|---|---|---|
| A | 21 | Sticks to saw |
| B | 48 | Sticks to saw |
| 1 | 62-64 | Cleanly diced |
| 2 | 79-84 | Cleanly diced |
| 3 | 58-60 | Cleanly diced |
| 4 | 87-94 | Cleanly diced |
| 5 | 74-80 | Cleanly diced |

### EXAMPLE 4

The viscosites of several different epoxy resin/fluxing agent mixtures were measured. Mixtures Z, Y, X, W, and V were each made by mixing 90 wt % epoxy resin (Z=EPON 1001, Y=EPON 1002, X=EPON 1004, W=EPON 1007, and V=EPON 1009) and 10% of fluxing agents PSPA (polysebaeic polyanhydride) together. Three solder balls, each having a 20-mil diameter, were placed on five separate copper substrates. One of the mixtures was printed on top of the solder balls on each substrate. Each printed substrates was then heated to 150° C. for 2 minutes followed immediately by 190° C. for 1 minute. Observations of the solder are shown in Table 5. Also in Table 5, the viscosities of each mixture are reported. Using the single point analysis of Rheometric Scientific Instrument at 100 rad/s frequency, 5% strain temperature of 190° C., and 50 mm parallel plates were used to determine each of the viscosities.

TABLE 5
Solder Flux Observations

| | Viscosity at | Solder Flux |
|---|---|---|
| Sample | 190° C. (cP) | Observation |
| Z | 874 | Complete Fluxing |
| Y | 2,905 | Complete Fluxing |
| X | 5,951 | Partial Fluxing |
| W | 16,615 | No Fluxing |
| V | 351,141 | No Fluxing |

As shown in Table 5, resins with a viscosity of about 5,900 cP or lower are preferable to accommodate the fluxing capability.

The degree to which fluxing occurs is measurable by the change in the radius of the solder balls. The radii of the solder balls containing various fluxing agents were measured and the results are shown in Table 6.

TABLE 6
Fluxing Agents

| Acid | PKa | Radius of Solder (mil) |
|---|---|---|
| Citric | 3.14 | 35.68 |
| Corfree M2 | 4.59 | 31.67 |
| L-cysteine | 7.85 | 10.00 |
| Resorcinol | 9.87 | 10.00 |
| Hydroquinone | 10.35 | 10.00 |

As shown in Table 6, citric acid and Corfree M2 were preferable among the fluxing agents that were tested. The flux capability of the formulations listed in Table 1 was tested using the method as described above. All the formulations in Table 1 show the enlargement of the solder ball in radius.

### EXAMPLE 5

The following example shows the effect of the type of catalyst on the curing behavior of the B-staged epoxy-oligomer based underfill coatings. The thermal curing profiles of the B-Staged coatings in DSC were used to prove the latent curing ability of the catalyst with the underfill formulations.

To prepare the composition, 100 parts of Epon 1001 F (Bisphenol-A glycidyl ether oligomer from Resolution Performance Products) was dissolved in 67 parts of γ-Butyrolactone (Aldrich Chemical) at 140° C. for 1 hour. After cooling the homogeneous mixture to room temperature, 10 parts of Corefree M2 (Dodecanedioic Acid from DuPont as fluxing agent), 0.25 parts of defoamer Agitan 731 (Dee Foo Products), 0.5 parts of A-187 (Silquest), and 0.25 parts of a catalyst (as specified in Table 7) were added.

After all the components had been hand-mixed together, they were passed through a 3-Roll Mill and degassed in a vacuum oven at room temperature. All formulations were uniform and bubble free and had viscosity close to 3500 cP (Brookfield viscometer at 5 rpm).

To evaluate the curing, the underfill materials were dispensed on glass cover-slips (25×25 mm), by a stenciling process, to get 175 micron thick coating. The B-Stage was done in a convection oven, pre-heated to 140° C., for 30 minutes. After B-stage, all coatings were smooth, non-tacky and void free. These B-staged coatings were then used for the curing study.

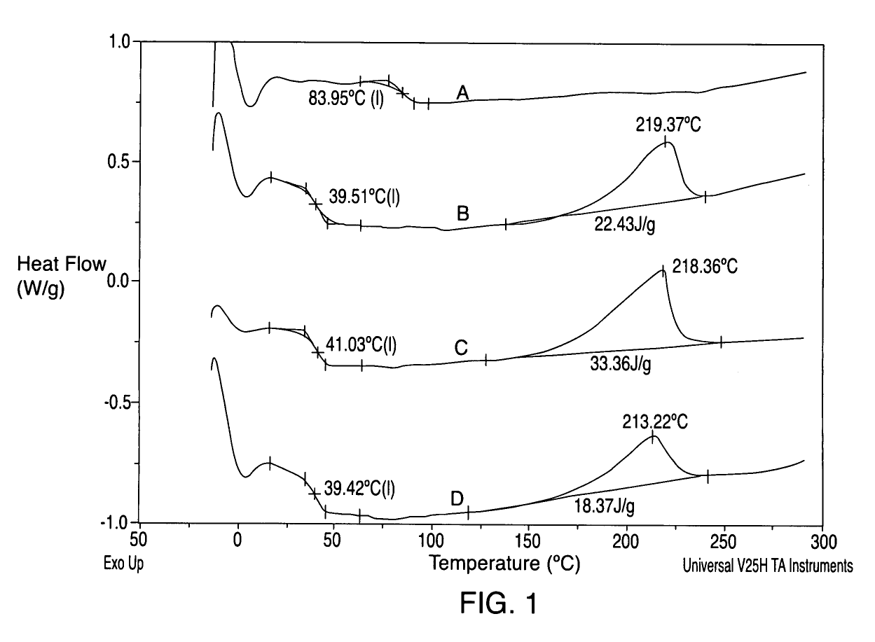

The peak curing temperatures and the enthalpy of curing of the B-staged epoxy-ligomer based underfill systems (with different catalysts at 0.25% epoxy wt. basis) were recorded from the DSC curing profiles (ramped at 20° C./min.) and are shown in Table 7. After the DSC samples had cooled down to room temperature, they were ramped again (@10° C./min. this time) to record the cured Tg. The DSC curing thermograms are shown in FIG. 1.

TABLE 1
Epoxy-oligomer based underfills with different catalysts

| | | 2P4MZ- | | | B-Stage | Curing | Curing | Cured |
|---|---|---|---|---|---|---|---|---|
| | | PMDA | AMICURE | Curezol | Tg | Peak | Enthalpy | Tg |
| Formula | 2P4MZ | adduct | 2PIP | 17Z | (° C.) | (° C.) | (J/g) | (° C.) |
| A | 0.25 | — | — | — | 83.9 | None | None | 84.0 |
| B | — | 0.25 | — | — | 39.5 | 219.4 | 22.4 | 63.1 |
| C | — | — | 0.25 | — | 41.0 | 218.4 | 33.4 | 68.3 |
| D | — | — | — | 0.25 | 39.4 | 213.2 | 18.4 | 52.1 |

As illustrated in Table 7 and FIG. 1, 2P4MZ (in Formulation A) cures the coating completely during the B-stage step and no cure exotherm is observed in the DSC ramp. The identical Tgs after B-stage and the DSC cure (the cured Tg) also show significant enhancement during B-stage. This premature curing during B-stage results in poor flow and interferes with the solder interconnection during reflow.

For systems B-D, the curing exotherms are delayed beyond 200° C. (beyond tin/lead liquidus at 183° C. and close to typical lead-free solder melting temperatures). This delay in curing (compared to traditional 2P4MZ type imidazole curing agents) provides larger time window for the solder to flux and form interconnection before the underfill resin has cured. When solder-bumped chips, coated with formulations (B-D) were assembled by passing through the standard solder-reflow process, good fluxing, reflow and interconnection of the solder bumps to the substrate were established. In case of the bumped chips coated with Formulation A, the cured underfill material did not flow during reflow and solder interconnection could not be achieved.

Among the three formulations (B-D), Formulation C provides the highest B-stage Tg and curing enthalpy. The higher B-stage Tg is desirable to ensure clean dicing of the wafer. The higher curing enthalpy indicates broader B-stage window with more reaction taking place during the reflow (rather than the B-stage step).

Many modifications and variations of this invention can be made without departing from its spirit and scope, as will be apparent to those skilled in the art. The specific embodiments described herein are offered by way of example only, and the invention is to be limited only by the terms of the appended claims, along with the full scope of equivalents to which such claims are entitled.

We claim:

1. A B-stageable underfill encapsulant, wherein the encapsulant solidifies at a first temperature during the B-stage process to produce a smooth, non-tacky surface on a semiconductor wafer or silicon chip and wherein substantially the entire encapsulant cures at a second temperature that is higher than the first temperature, wherein the encapsulant comprises:
a) a thermal curable resin;
b) an imidazole phosphate salt catalyst;
c) at least one solvent;
d) one or more fluxing agents; and
e) optionally, one or more of the group consisting of surfactants, wetting agents, defoaming agents, coupling agents, inorganic fillers, adhesion promoters, flow additives, air release agents, and mixtures thereof.

2. The encapsulant of claim 1, wherein the thermal curable resin is selected from the group consisting of monofunctional and multifunctional glycidyl ethers of Bisphenol-A, monofunctional and multifunctional glycidyl ethers of Bisphenol-F, aliphatic epoxies, aromatic epoxies, saturated epoxies, unsaturated epoxies, cycloaliphatic epoxy resins, epoxies having the structures 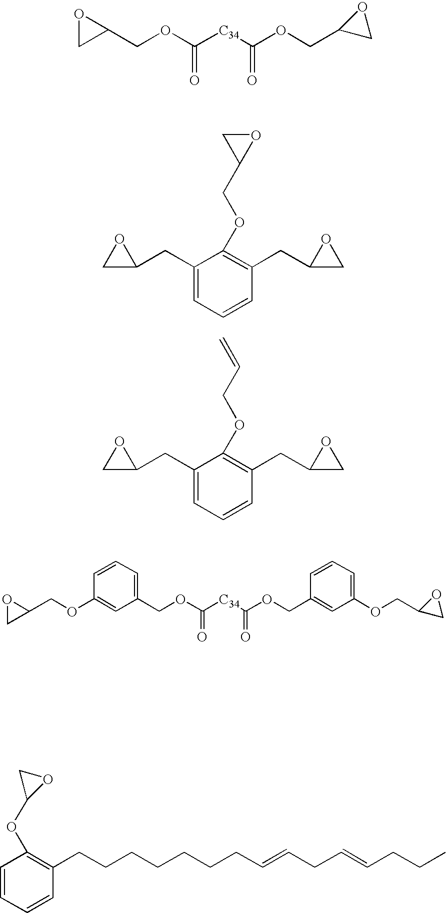
and mixtures thereof.

3. The encapsulant of claim 2, wherein the thermal curable resin is selected from the group consisting of 3,4-epoxycyclohexylmethyl-3,4-epoxycyclohexane carboxylate, vinylcyclohexene dioxide, 3,4-epoxy-6-methyl cyclohexyl methyl-3,4-epoxycyclohexane carboxylate, dicyclopentadiene dioxide, bisphenol A epoxy resin, bisphenol F epoxy resin, epoxy novolac resin, poly(phenyl glycidyl ether)-co-formaldehyde, biphenyl type epoxy resin, dicyclopentadiene-phenol epoxy resins, naphthalene epoxy resins, epoxy functional butadiene acrylonitrile copolymers, epoxy functional polydimethyl siloxane, and mixtures thereof.

4. The encapsulant of claim 3 wherein the thermal curable resin comprises in the range of about 20 wt % to about 90 wt % of the encapsulant.

5. The encapsulant of claim 5, wherein the thermal curable resin comprises in the range of about 20 wt % to about 80 wt % of the encapsulant.

6. The encapsulant of claim 1, wherein the imidazole phosphate salt comprises 2-phenyl imidazole dihydrogen phosphate salt.

7. The encapsulant of claim 6, wherein the imidazole phosphate salt comprises a phosphoric acid content.

8. The encapsulant of claim 1, wherein the imidazole phosphate salt comprises in the range of about 0.01 wt % to about 10 wt % of the encapsulant.

9. The encapsulant of claim 8, wherein the imidazole phosphate salt comprises in the range of about 0.1 wt % to about 5 wt % of the encapsulant.

10. The encapsulant of claim 1, wherein the at least one solvent is selected from the group comprising solvents that are stable and dissolve the epoxy resins in the composition.

11. The encapsulant of claim 9, wherein the at least one solvent is selected from the group consisting of ketones, esters, alcohols, ethers, γ-butyrolactone and propylene glycol methyl ether acetate (PGMEA) and mixtures thereof.

12. The encapsulant of claim 11, wherein the at least one solvent is selected from the group consisting of γ-butyrolactone, propylene glycol methyl ether acetate (PGMEA) and mixtures thereof.

13. The encapsulant of claim 9, wherein the solvent comprises up to about 80 wt % of the encapsulant.

14. The encapsulant of claim 1 wherein the at least one fluxing agent is selected from the group consisting of carboxylic acids, rosin gum, dodecanedioic acid, adipic acid, sebasic acid, polysebasic polyanhydride, maleic acid, tartaric acid, citric acid, alcohols, hydroxyl acid and hydroxyl base, polyols, ethylene glycol, glycerol, 3-[bis(glycidyl oxy methyl) methoxy]-1,2-propane diol, D-ribose, D-cellobiose, cellulose, 3-cyclohexene-1,1-dimethanol, and mixtures thereof.

15. (The encapsulant of claim 14, wherein the at least one flux agent comprises rosin gum, dodecanedioic acid, adipic acid, or mixtures thereof.

16. The encapsulant of claim 15, wherein the at least one flux agent comprises in the range of about 0.5 wt % to about 20 wt % of the encapsulant.

17. The encapsulant of claim 16, wherein the at least one flux agent comprises in the range of about 1 wt % to about 10 wt % of the encapsulant.

18. The encapsulant of claim 1, wherein the encapsulant further comprises one or more of group consisting of surfactants, wetting agents, defoaming agents, coupling agents, inorganic fillers, adhesion promoters, flow additives, air release agents, and mixtures thereof.

19. The encapsulant of claim 18, wherein the surfactant is selected from the group consisting of organic acrylic polymers, silicones, epoxy-silicones, polyoxyethylene/polyoxypropylene block copolymers, ethylene diamine based polyoxyethylene/polyoxypropylene block copolymers, polyol-based polyoxyalkylenes, fatty alcohol-based polyoxyalkylenes, fatty alcohol polyoxyalkylene alkyl ethers and mixtures thereof.

20. A silicon wafer having a B-stageable underfill composition that is curable at a single temperature deposited on one face of the wafer, the B-stageable composition comprising
a) a thermal curable resin;
b) an imidazole phosphate salt catalyst;
c) at least one solvent;
d) one or more fluxing agents; and
e) optionally, one or more additive selected from the group consisting of surfactants, wetting agents, defoaming agents, coupling agents, inorganic fillers, adhesion promoters, flow additives, air release agents, and mixtures thereof.

21. A method of preparing one or more silicon chips, comprising the steps of
a) applying the encapsulant of claim 1 to a semiconductor wafer;
b) B-stage processing the encapsulant on the semiconductor wafer so that the encapsulant solidifies into a smooth, non-tacky coating; and
c) dicing the semiconductor wafer into individual silicon chips.

22. The method of claim 21, wherein the encapsulant is applied to the semiconductor wafer via spin coating, screen printing or stencil printing.

23. A method of preparing an electronic package comprising the steps of
a) applying the encapsulant of claim 1 to a semiconductor wafer;
b) B-stage processing the encapsulant on the semiconductor wafer so that the encapsulant solidifies into a smooth, non-tacky coating;
c) dicing the semiconductor wafer into multiple silicon chips, with each chip having a first side coated with the encapsulant;
d) placing one or more silicon chips on a substrate so that the first side of the silicon chip is adjacent to the substrate; and
e) heating the one or more silicon chips and substrate to a temperature sufficient to form interconnections between the one or more silicon chips and the substrate.

24. The method of claim 23, comprising the additional step of placing an unfilled liquid curable fluxing material on the substrate before the silicon chip is placed on the substrate.

25. The method of claim 24, wherein the unfilled liquid curable fluxing material comprises
a) a thermal curable epoxy resin;
b) an imidazole-anhydride adduct; and
c) at least one fluxing agent,
wherein the imidazole-anhydride adduct comprises an adduct of 2-phenyl-4-methyl imidazole and pyromellitic dianhydride.
